(19) United States
(12) Patent Application Publication
(10) Pub. No.: US 2021/0099150 A1
(43) Pub. Date: Apr. 1, 2021

(54) ELECTROMAGNETIC WAVE NOISE ABSORBERS FOR SMARTPHONES AND RELATED DEVICES

(71) Applicant: Yuki Itabashi, Kukushima (JP)

(72) Inventor: Yuki Itabashi, Kukushima (JP)

(21) Appl. No.: 17/120,281

(22) Filed: Dec. 14, 2020

Related U.S. Application Data
(63) Continuation of application No. PCT/JP2020/004207, filed on Jan. 24, 2020.

(30) Foreign Application Priority Data
May 15, 2019 (JP) 2019-103253

(51) Int. Cl. H03H 7/01

(52) U.S. Cl. CPC H03H 7/0123

(57) ABSTRACT

A smartphone and such devices use an ultra-high-speed digital signal. Thus, an electromagnetic wave noise emits inside. Once the electromagnetic wave noise emits in the smartphone and such devices, it stays inside. When the electromagnetic wave noise is released outside, an original accurate digital signal and an original accurate analog signal can be obtained. The sound of the smartphone and such devices becomes clear. By using a USB cable, a power supply line terminal and a ground line terminal of the electromagnetic wave noise absorber respectively connect to the power supply line terminal and the ground line terminal of the smartphone and such devices. By using a noise filter circuit and an electromagnetic noise absorber copper plate, the electromagnetic wave noise absorber absorbs the electromagnetic wave noise from the smartphone and such devices. The electromagnetic wave noise disappears in the electromagnetic noise absorber copper plate.

### RELATED APPLICATIONS

This application claims priority under 35 U.S.C. § 120 to, and is a continuation of, co-pending International Application PCT/JP2020/004207, filed Jan. 24, 2020 and designating the US, which claims priority to Japanese Application 2019-103253, filed May 15, 2019, such Japanese Application also being claimed priority to under 35 U.S.C. § 119. These Japanese and International applications are incorporated by reference herein in their entireties.

### BACKGROUND

### Field

The present invention relates to an electromagnetic wave noise absorber for a smartphone and such devices. The smartphone and such devices include the smartphone, a portable digital audio device, a tablet terminal, a Bluetooth speaker, a Bluetooth headphone, and a Bluetooth earphone.

A smartphone and such devices use a digital circuit. The digital circuit handles a pulse wave signal that switches between a high level and a low level. At the moment when a signal level changes, an ultra-high frequency current flows through a signal line. At this time, the ultra-high frequency current flows through a power supply line and a ground line. When the ultra-high frequency current flows in the digital circuit, an electromagnetic wave noise emits in the digital circuit. The electromagnetic wave noise damages circuits in other parts of an electronic digital device. The electromagnetic wave noise includes a normal mode noise that flows through the signal line and a common mode noise that flows through the power supply line and the ground line. For example, as shown in FIG. 1, the electromagnetic wave noise in the power supply line and the ground line are the common mode noise. An effect of the common mode noise in other parts of the digital circuit is particularly great. A design of the electronic digital device that uses the digital circuit takes a countermeasure to reduce the common mode noise.

An operating frequency of the smartphone and such devices increases a frequency to improve a performance. Thus, an ultra-high frequency electromagnetic wave noise emits. The ultra-high frequency electromagnetic wave noise spreads over a wide area and damages circuits in other parts of the electronic digital device. For example, as shown in FIG. 1, the electromagnetic wave noise of the digital IC1 spreads over the digital IC2.

The electromagnetic wave noise damages a digital analog converter (DAC) that converts a digital signal of the sound into an analog signal. Thus, the electromagnetic wave noise does not clear the sound of the smartphone and such devices and loses clarity of the sound.

The countermeasure to reduce the common mode noise is basically to prevent the electromagnetic wave noise from emitting. However, the digital circuit having a high operating frequency emits the electromagnetic wave noise. A noise filter circuit is used as the countermeasure to reduce the common mode noise. The noise filter circuit composes typically with parts of a line bypass capacitor and a common mode choke coil. The line bypass capacitor is connected to a shield ground case.

The electromagnetic wave noise may appear in the shield ground case connecting the line bypass capacitor. In this case, it is necessary to make a new ground separating from the shield ground case.

The common mode noise transmits through the power supply line and the ground line. When the electromagnetic wave noise emits, it becomes difficult to stop the propagation. The electromagnetic wave noise emitting in the smartphone and such devices stays inside without releasing outside. The sound of the smartphone and such devices continues doing not clear because the electromagnetic wave noise staying inside.

Incorporated by Reference: Non-Patent Literature 1, Murata Manufacturing homepage: Noise reduction basic course. Chapters 1 to 6. (murata.com/ja-jp/products/emc/emifil/knowhow/basic); Non Patent Literature 2, TDK homepage: EMC Design Guide. Basic, Product, Practice. (product. tdk.com/info/ja/products/emc/gudebook/index.html); Non Patent Literature 3, TDK homepage: TDK Techno Magazine. Noise (EMC) introduction 1. 1st to 11^{th} (tdk.co.jp/techmag/emc/index. htm); Non Patent Literature 4, TDK homepage: TDK Techno Magazine. Noise (EMC) introduction 2. 1st to 10th (tdk.co.jp/techmag/emc2/index. htm).

### SUMMARY

### Technical Problem

The smartphone and such devices use the DAC to convert the digital signal of the sound into the analog signal and reproduce the sound. The smartphone and such devices use an ultra-high-speed digital signal. Thus, the electromagnetic wave noise emits in the smartphone and such devices. The digital signal of the sound is mixed with the electromagnetic wave noise emitting inside. The digital signal mixing with the electromagnetic wave noise is different from an original accurate digital signal. The digital signal mixing with the electromagnetic wave noise cannot reproduce an original accurate sound. The sound of the smartphone and such devices becomes unclear.

The smartphone and such devices take the countermeasure to prevent the electromagnetic wave noise from emitting inside. However, the ultra-high-speed digital signal emits the electromagnetic wave noise. The electromagnetic wave noise emitting in the power supply line and the ground line of the smartphone and such devices stays inside and is not released outside. The electromagnetic wave noise emitting in the power supply line and the ground line propagates to other parts in the digital circuit and has an adverse effect. When the electromagnetic wave noise emitting in the supply power line and the ground line is released outside, the digital signal mixing with the electromagnetic wave noise becomes the original accurate digital signal. Thus, the sound which converted the original accurate digital signal into the analog signal by using the DAC becomes clear. The problem is how to release the electromagnetic wave noise in the power supply line and the ground line of the smartphone and such devices to outside.

### Solution to Problem

A smartphone and such devices transmit a digital signal to external digital devices by using a USB cable. The USB cable uses a digital signal wire for transmitting the digital signal. Additionally, the USB cable uses a power supply line wire and a ground line wire for charging the smartphone and such devices.

As shown in a block diagram of FIG. 2, an electromagnetic wave noise absorber connects to the smartphone and such devices by using the USB cable. By using the USB cable, the electromagnetic wave noise mixing in a power supply line of the smartphone and such devices flows into the power line terminal of the electromagnetic wave noise absorber from the power line terminal of the smartphone and such devices. The electromagnetic wave noise absorber receives the electromagnetic wave noise in the power supply line. By using the USB cable, the electromagnetic wave noise mixing in a ground line of the smartphone and such devices flows into the ground line terminal of the electromagnetic wave noise absorber from the ground line terminal of the smartphone and such devices. The electromagnetic wave noise absorber receives the electromagnetic wave noise in the ground line. The electromagnetic wave noise absorber absorbs the electromagnetic wave noise in the power supply line and in the ground line and extinguishes them. The smartphone and such devices release the electromagnetic wave noise to outside. The electromagnetic wave noise does not stay inside. Thus, as shown in FIG. 3, the digital signal mixing with the electromagnetic wave noise becomes an original accurate digital signal. When the original accurate digital signal of the sound is converted into the analog signal by using a digital analog converter (DAC), it becomes an original accurate analog signal and the sound becomes clear.

### Advantageous Effects of Invention

The electromagnetic wave noise absorber connects to the smartphone and such devices by using the USB cable. The electromagnetic wave noise absorber absorbs the electromagnetic wave noise staying in the smartphone and such devices and disappears. The sound of the smartphone and such devices becomes clear because the electromagnetic wave noise disappears.

When a user of a smartphone makes a phone call, it is common to bring the smartphone close to the ear of the user. At this time, the head of the user receives the electromagnetic wave noise emitting from a shield ground case of the smartphone. When it lasts for a long time, the brain of the user is adversely affected. The electromagnetic wave noise absorber absorbs the electromagnetic wave noise staying in the shield ground case and disappears. Thus, when the user calls for a long time, the head and the brain of the user do not be adversely affected because no electromagnetic wave noise.

The electromagnetic wave noise absorber connects to the smartphone and such devices by using the USB cable. The method of absorbing the electromagnetic wave noise from the power supply line and the ground line of a USB connector terminal can be applied to any digital devices having the USB connector terminal. For example, smartphones, portable digital audios, tablet terminals, Bluetooth speakers, Bluetooth headphones, and Bluetooth earphones.

### BRIEF DESCRIPTION OF DRAWINGS

FIG. 1 is an explanatory diagram showing that an electromagnetic wave noise causes disability in other parts of a smartphone and such devices.

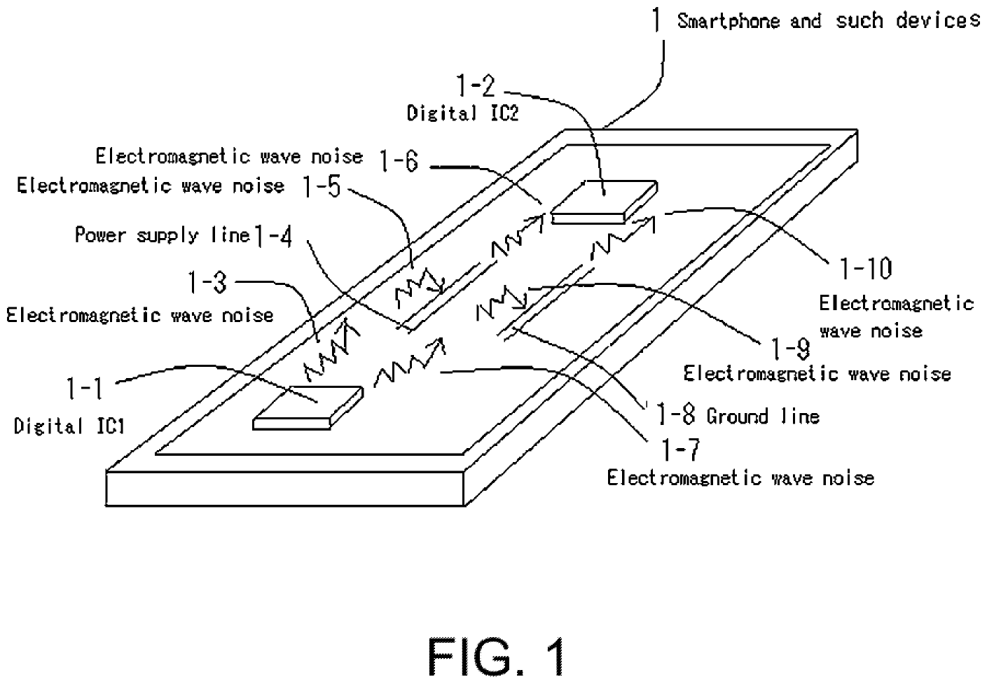

FIG. 2 is a block diagram of the electromagnetic wave noise absorber of the present invention.

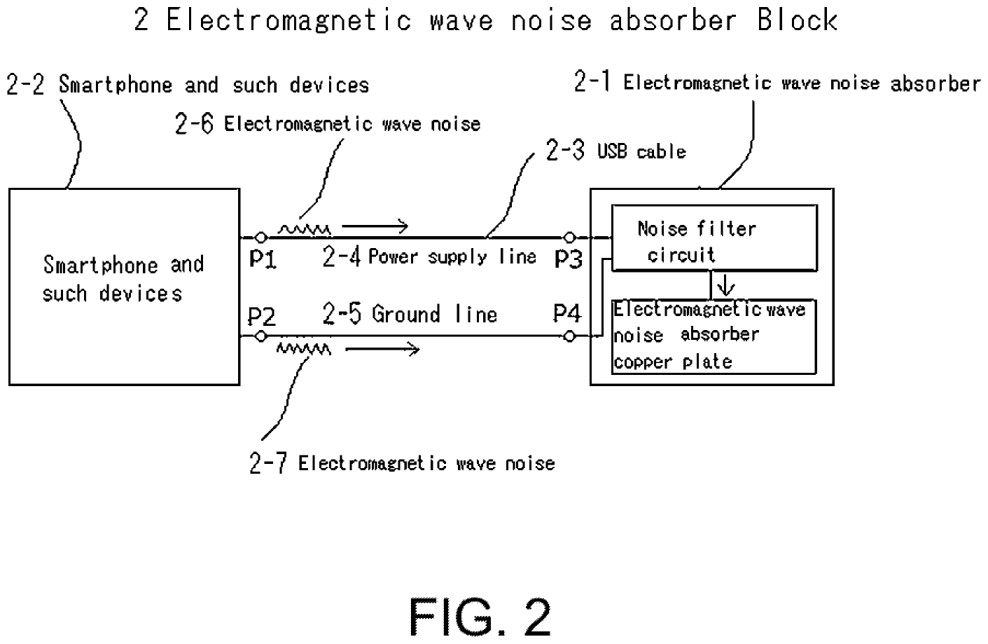

FIG. 3 is an explanatory diagram showing that a digital signal mixing with the electromagnetic wave noise becomes an original accurate digital signal which the electromagnetic wave noise disappears.

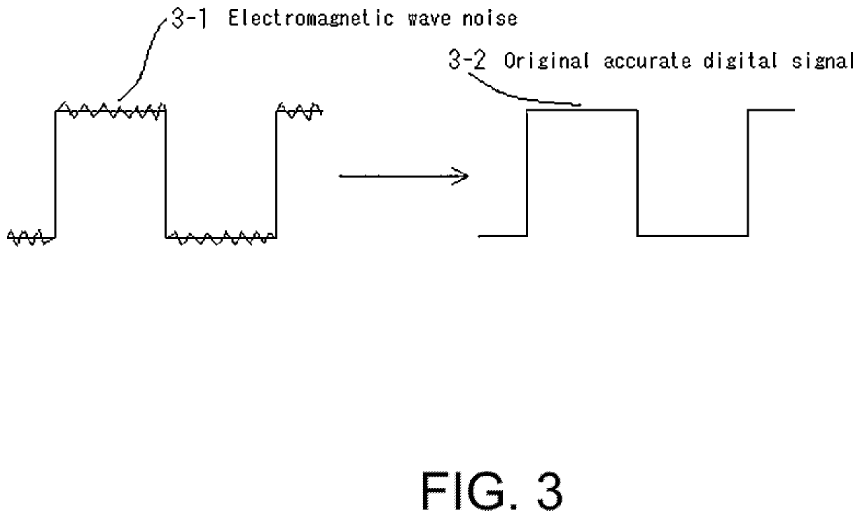

FIG. 4 is a circuit diagram of the electromagnetic wave noise absorber of the present invention.

### DETAILED DESCRIPTION

A power supply line terminal of an electromagnetic wave noise absorber connects to the power supply line terminal of a smartphone and such devices by using a USB cable. A ground line terminal of the electromagnetic wave noise absorber connects to the ground line terminal of the smartphone and such devices by using the USB cable. The electromagnetic wave noise absorber receives an electromagnetic wave noise from the smartphone and such devices. A noise filter circuit and an electromagnetic wave noise absorber copper plate in the electromagnetic wave noise absorber absorb the electromagnetic wave noise. The electromagnetic wave noise disappears in the electromagnetic wave noise absorber copper plate. The noise filter circuit of the present invention composes with a resistor, a line bypass capacitor, and a common mode choke coil.

There are various types of USB connector terminals for the smartphone and such devices. Also, there are various types of USB cable sockets for the smartphone and such devices. For example, Type-A, Type-B, Type-C, Type-Mini-A, Type-Mini-B, Type-Micro-A, and Type-Micro-B. A user of the smartphone and such devices uses a USB cable socket that is compatible with a USB connector terminal. The user connects the smartphone and such devices to a charger by using the USB cable. The charger uses typically a USB Type-A connector terminal. Consequently, the USB cable socket for the charger uses a USB Type-A cable socket. The electromagnetic wave noise absorber uses the USB Type-A connector terminal. Thus, the smartphone and such devices can connect to the electromagnetic wave noise absorber by using the USB cable used for the charger.

### Example

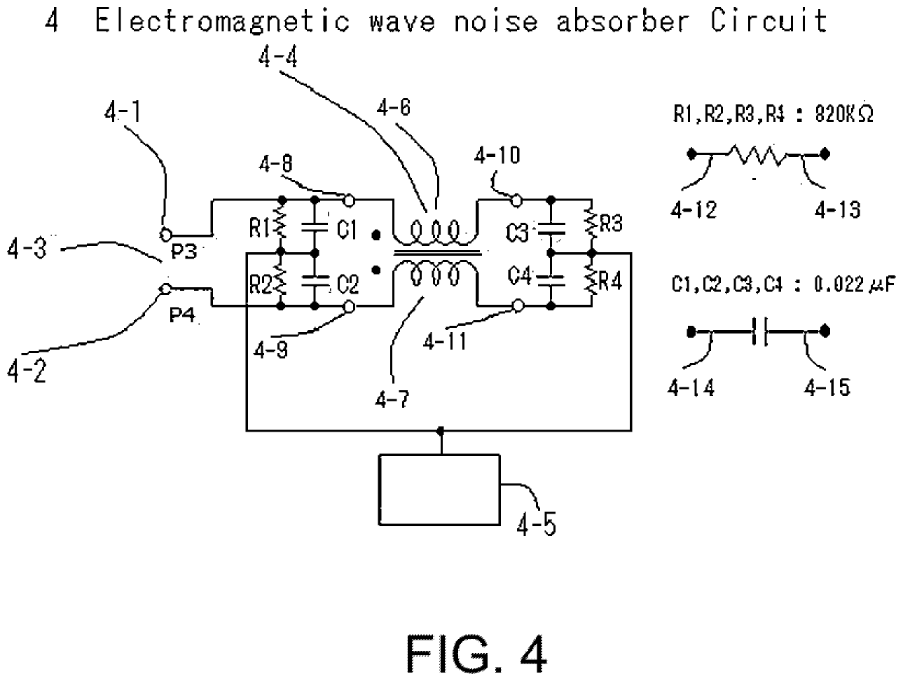

FIG. 4 is a circuit diagram of an electromagnetic wave noise absorber of the present invention. A power supply line terminal of a USB Type-A connector terminal 4-1 connects to a first coil input side terminal 4-8 of a common mode choke coil 4-4 of inductance 2 mH. A ground line terminal 4-2 of the USB Type-A connector 4-3 terminal connects to a second coil 4-7 input side terminal 4-9 of the common mode choke coil 4-4. A first lead wire 4-12 of a first resistor of resistance 820KΩ connects to the first coil input side terminal 4-8 of the common mode choke coil 4-4. A second lead wire 4-13 of the first resistor connects to an electromagnetic wave noise absorber copper plate 4-5 of thickness 0.5 mm or more and size 9000 square mm or more. A first lead wire 4-14 of a first line bypass capacitor of capacitance 0.022 μF connects to the first coil 4-6 input side terminal 4-8 of the common mode choke coil 4-4. A second lead wire 4-15 of the first line bypass capacitor connects to the electromagnetic wave noise absorber copper plate 4-5. A first lead wire 4-12 of a second resistor of resistance 820KΩ connects to the second coil 4-7 input side terminal 4-9 of the common mode choke coil 4-4. A second lead wire 4-13 of the second resistor connects to the electromagnetic wave noise absorber copper plate 4-5. A first lead wire 4-14 of a second line bypass capacitor of capacitance 0.022 μF connects to the second coil 4-7 input side terminal 4-9 of the common mode choke coil 4-4. A second lead wire 4-15 of the second line bypass capacitor connects to the electromagnetic wave noise absorber copper plate 4-5. A first lead wire 4-12 of a third resistor of resistance 820KΩ connects to a first coil 4-6 output side terminal 4-10 of the common mode choke coil 4-4. A second lead wire 4-13 of the third resistor connects to the electromagnetic wave noise absorber copper plate 4-5. A first lead wire 4-14 of a third line bypass capacitor of capacitance 0.022 μF connects to the first coil 4-6 output side terminal 4-10 of the common mode choke coil 4-4. A second lead wire 4-15 of the third line bypass capacitor connects to the electromagnetic wave noise absorber copper plate 4-5. A first lead wire 4-12 of a fourth resistor of resistance 820KΩ connects to a second coil 4-7 output side terminal 4-11 of the common mode choke coil 4-4. A second lead wire 4-13 of the fourth resistor connects to the electromagnetic wave noise absorber copper plate 4-5. A first lead wire 4-14 of a fourth line bypass capacitor of capacitance 0.022 μF connects to the second coil 4-7 output side terminal 4-11 of the common mode choke coil 4-4. A second lead wire 4-15 of the fourth line bypass capacitor connects to the electromagnetic wave noise absorber copper plate 4-5.

As shown in FIG. 4, two resistors and two line bypass capacitors having the same value are symmetrically arranged on an input side and an output side centering on the common mode choke coil 4-4. Four resistors and four line bypass capacitors connect to the electromagnetic wave noise absorber copper plate 4-5.

The electromagnetic wave noise absorber copper plate 4-5 is separated from a shield ground case. The electromagnetic wave noise absorber absorbs more efficiently the electromagnetic wave noise because this configuration. The sound of the smartphone and such devices becomes clear.

There is a clear difference in the sound because differences of the value of the resistor, the line bypass capacitor, and the common mode choke coil 4-4.

The sound is the clearest sound when the following value is used.

The resistor R1, R2, R3, R4: resistance 820KΩ.

The line bypass capacitor C1, C2, C3, C4: capacitance 0.022 μF.

The common mode choke coil L: inductance 2 mH.

There is the clear difference in the sound because differences of a copper plate thickness and a copper plate size of the electromagnetic wave noise absorber copper plate 4-5.

The sound is the clearest sound when the following value is used.

The copper plate 4-5 thickness: 0.5 mm or more.

The copper plate 4-5 size: 9000 square mm or more.

### INDUSTRIAL APPLICABILITY

In the circuit of the electromagnetic wave noise absorber, two resistors and two line bypass capacitors having the same value are symmetrically arranged on the input side and the output side centering on the common mode choke coil. A cord having an AC power input plug replaces the USB input terminal. An AC power output outlet adds to the output side of the common mode choke coil. By doing so, all acoustic devices that use an AC power source can use the electromagnetic wave noise absorber. When the AC power plug of an acoustic device inserts into the AC power output outlet of the electromagnetic wave noise absorber, the electromagnetic wave noise absorber absorbs the electromagnetic wave noise from the acoustic device. The electromagnetic wave noise of the acoustic device disappears. Thus, the sound of the acoustic device becomes clear.

1. An electromagnetic wave noise absorber, comprising:
a common mode choke having an input side terminal and an output side terminal;
a first resistive-capacitive circuit on the input side terminal, wherein the first resistive-capacitive circuit is configured to join to a USB connector;
a second resistive-capacitive circuit on the output side terminal;
an electromagnetic wave noise absorber plate connected to the first and the second resistive-capacitive circuit, wherein the plate has a length and a width that are both over 50 times a thickness of the plate.

2. The absorber of claim 1, wherein a first coil of the common mode choke is configured to connect directly to a power supply of the USB connector, and wherein a second coil of the common mode choke is configured to connect directly to a ground line of the USC connector.

3. The absorber of claim 2, wherein the USB connector is a USB Type-A connector.

4. The absorber of claim 1, wherein the first resistive-capacitive circuit includes a first resistor in parallel with a first capacitor and a second resistor in parallel with a second capacitor.

5. The absorber of claim 4, wherein the first resistor and the second resistor are in series between a first and a second coil of the common mode choke, and wherein the first capacitor and the second capacitor are in series between the first and the second coil of the common mode choke.

6. The absorber of claim 5, wherein the first resistor and the second resistor each have a resistance of 820KΩ, the first capacitor and the second capacitor each have a capacitance of 0.022 μF, and wherein the common mode choke has an inductance of 2 mH.

7. The absorber of claim 6, wherein the first and the second resistive-capacity circuit are symmetrical with the same types of components about the common mode choke.

8. The absorber of claim 6, wherein the plate is fabricated of copper, wherein the thickness is 0.5 mm or more, and wherein the length multiplied by the width is 9000 mm² or more.

9. The absorber of claim 1, wherein the first and the second resistive-capacitive circuit each include two resistors and two line bypass capacitors all connected between a first and a second coil of the common mode choke.

10. The absorber of claim 9, wherein the plate is fabricated of copper, wherein the thickness is 0.5 mm or more, and wherein the length multiplied by the width is 9000 mm² or more.

11. The absorber of claim 9, wherein the resistors each have a resistance of 820KΩ, wherein the capacitors each have a capacitance of 0.022 μF, and wherein the common mode choke has an inductance of 2 mH.

12. The absorber of claim 1, wherein the first resistive-capacitive circuit includes,
a first resistor connected directly between a first coil of the common mode choke and the plate,
a first capacitor connected directly between the first coil of the common mode choke and the plate,
a second resistor connected directly between a second coil of the common mode choke and the plate, and
a second capacitor connected directly between the second coil of the common mode choke and the plate.

13. The absorber of claim 12, wherein the first resistor is directly in parallel with the first capacitor and the second resistor is directly in parallel with the second capacitor.

14. The absorber of claim 12, wherein the plate is fabricated of copper, wherein the thickness is 0.5 mm or more, and wherein the length multiplied by the width is 9000 mm² or more.

15. The absorber of claim 12, wherein the resistors each have a resistance of 820KΩ, and wherein the capacitors each have a capacitance of 0.022 μF

16. The absorber of claim 15, wherein the common mode choke has an inductance of 2 mH.

17. The absorber of claim 12, wherein the first and the second resistive-capacity circuit are symmetrical with the same types of components about the common mode choke.

18. The absorber of claim 12, wherein the first coil of the common mode choke is configured to connect directly to a power supply of the USB connector, and wherein the second coil of the common mode choke is configured to connect directly to a ground line of the USC connector.

19. An electromagnetic wave noise absorber for use with a USB connection, comprising:
a power supply line terminal of a USB connector terminal connected to a first coil input side terminal of a common mode choke coil;
a ground line terminal of the USB connector terminal connected to a second coil input side terminal of the common mode choke coil;
a first lead wire of a first resistor connected to the first coil input side terminal of the common mode choke coil;
a second lead wire of the first resistor connected to an electromagnetic wave noise absorber plate;
a first lead wire of a first line bypass capacitor connected to the first coil input side terminal of the common mode choke coil;
a second lead wire of the first line bypass capacitor connected to the electromagnetic wave noise absorber plate;
a first lead wire of a second resistor connected to the second coil input side terminal of the common mode choke coil;
a second lead wire of the second resistor connected to the electromagnetic wave noise absorber plate;
a first lead wire of a second line bypass capacitor connected to the second coil input side terminal of the common mode choke coil;
a second lead wire of the second line bypass capacitor connected to the electromagnetic wave noise absorber plate;
a first lead wire of a third resistor connected to a first coil output side terminal of the common mode choke coil;
a second lead wire of the third resistor connected to the electromagnetic wave noise absorber plate;
a first lead wire of a third line bypass capacitor connected to the first coil output side terminal of the common mode choke coil;
a second lead wire of the third line bypass capacitor connected to the electromagnetic wave noise absorber plate;
a first lead wire of a fourth resistor connected to a second coil output side terminal of the common mode choke coil;
a second lead wire of the fourth resistor connected to the electromagnetic wave noise absorber plate;
a first lead wire of a fourth line bypass capacitor connected to the second coil output side terminal of the common mode choke coil; and
a second lead wire of the fourth line bypass capacitor connected to the electromagnetic wave noise absorber plate.

20. The absorber of claim 19, wherein the first, the second, the third, and the fourth resister each has a resistance of 820KΩ, and wherein the first, the second, the third, and the fourth line bypass capacitor each has a capacitance of 0.022 μF.
